(19) United States
(12) Patent Application Publication
(10) Pub. No.: US 2012/0034793 A1
(43) Pub. Date: Feb. 9, 2012

(54) METHOD FOR FORMING METAL NITRIDE FILM

(75) Inventors: Kensaku Narushima, Nirasaki-shi (JP); Akinobu Kakimoto, Nirasaki-shi (JP); Takanobu Hotta, Nirasaki-shi (JP)

(73) Assignee: TOKYO ELECTRON LIMITED, Tokyo (JP)

(21) Appl. No.: 13/243,075

(22) Filed: Sep. 23, 2011

Related U.S. Application Data
(63) Continuation of application No. PCT/JP2010/054981, filed on Mar. 23, 2010.

(30) Foreign Application Priority Data
Mar. 27, 2009 (JP) 2009-079723

(51) Int. Cl. H01L 21/283

(52) U.S. Cl. 438/785; 257/E21.159

(57) ABSTRACT

A wafer serving as a target substrate to be processed is loaded into a chamber, and an inside of the chamber is maintained under a vacuum level. Then, a TiN film is formed on the wafer by alternately supplying TiCl₄ gas and MMH gas into the chamber while heating the wafer. NH₃ gas is supplied in conjunction with the supply of the hydrazine compound gas.

This application is a Continuation Application of PCT International Application No. PCT/JP2010/054981 filed on Mar. 23, 2010, which designated the United States.

### FIELD OF THE INVENTION

The present invention relates to a metal nitride film forming method for forming a metal nitride film, e.g., a TiN film.

### BACKGROUND OF THE INVENTION

In the manufacture of semiconductor devices, a TiN film, for example, is used as a material for a barrier film or an electrode. For a film forming method, CVD (Chemical Vapor Deposition) is employed since satisfactory step coverage is achieved even in a fine circuit pattern by using the CVD. Further, as film forming gases, TiCl₄ gas and NH₃ gas are conventionally used (see, e.g., Japanese Patent Application Publication No. H06-188205),

Conventionally, the TiN film formation using the TiCl₄ gas and the NH₃ gas is carried out at a film formation temperature of about 600° C. However, there has been suggested a low temperature-oriented technique for performing a film forming process at a lower temperature of about 450° C. by repeating processes of alternately supplying the TiCl₄ gas and the NH₃ gas, while performing a purge step therebetween, conforming with scaling-down of various devices and consolidation of different kinds of devices (see, e.g., Japanese Patent Application Publication No. 2003-077864). Further, attempts have been made to lower the film formation temperature to a lower level.

However, a TiN film formed at a low temperature by using the TiCl₄ gas and the NH₃ gas is disadvantageous in that (1) the film formation speed is slow, (2) the concentration of Cl in the film is high and the density of the film is low, (3) it is difficult to form it as a continuous film, and (4) it is easily oxidized when formed as an insulating film, for example. Especially, the low film formation speed in the point (1) results in the decrease in the productivity, which may be considered as one of significant problems. The increase in the resistivity is brought about by the point (2) where the concentration of Cl in the film is high. Besides, due to the point (3) where it is difficult to form it as a continuous film, the barrier property is deteriorated.

### SUMMARY OF THE INVENTION

In view of the above, the present invention provides a metal nitride film forming method, capable of being performed at a lower temperature and at a higher film formation speed.

The present invention also provides a metal nitride film forming method, capable of forming a metal nitride film having a low resistivity at a lower temperature.

The present invention also provides a metal nitride film forming method, capable of forming a metal nitride film having a high barrier property at a lower temperature.

Further, the present invention provides a storage medium for storing a program which is designed to execute the above metal nitride film forming methods.

In accordance with a first aspect of the present invention, there is provided a method for forming a metal nitride film. The method includes loading a target substrate to be processed into a processing chamber and maintaining an inside of the processing chamber under a depressurized state; maintaining the target substrate in the processing chamber at a temperature of 400° C. or lower; and forming a metal nitride film on the target substrate by alternately supplying a metal chloride gas and a hydrazine compound gas into the processing chamber. NH₃ gas is supplied in conjunction with the supply of the hydrazine compound gas

In accordance with a second aspect of the present invention, there is provided a method for forming a metal nitride film. The method includes maintaining a target substrate to be processed at a temperature ranging between 50 and 230° C. including 50° C. and forming a TiN film mainly of an amorphous state on the target substrate by alternately supplying TiCl₄ gas and monomethyl hydrazine gas into the target substrate; and maintaining the target substrate at a temperature ranging from 230 to 330° C. and forming a TiN film mainly of a TiN crystalloid state on the TiN film mainly of the amorphous state by alternately supplying TiCl₄ gas and monomethyl hydrazine gas into the target substrate.

### BRIEF DESCRIPTION OF THE DRAWINGS

FIG. 1 is a schematic cross sectional view showing an example of a film forming apparatus in use for performing a metal nitride film forming method in accordance with an embodiment of the present invention;

FIG. 2 is a timing view showing several sequence examples of the film forming method in accordance with the present embodiment;

FIG. 3 shows a relationship between a temperature and a heat discharge rate when MMH is heated;

FIG. 4A is a model showing a case where a wafer temperature exceeds a self decomposition ending temperature of 330° C. when a TiN film is formed on the bottom of a contact hole by using TiCl₄ gas and MMH gas;

FIG. 4B is a model showing a case where a wafer temperature is lower than 230° C. when a TiN film is formed on the bottom of a contact hole by using TiCl₄ gas and MMH gas;

FIG. 5 shows a temperature dependency of a backside deposition amount, serving as an index of step coverage, when a TiN film is actually formed by using TiCl₄ gas and MMH gas;

FIG. 6 shows a configuration of a DRAM including a TiN film serving as an upper electrode;

FIG. 7 shows relationships between a wafer temperature and a film thickness in case when a film is formed by using MMH gas as nitriding gas and in another case when a film is formed by using NH₃ gas as nitriding gas;

FIG. 8 shows relationships between a wafer temperature and a resistivity in case when a film is formed by using MMH gas as nitriding gas and in case when a film is formed by using NH₃ gas as nitriding gas;

FIG. 9 is SEM pictures showing surfaces of TiN films formed by using TiCl₄ gas and MMH gas at temperatures of 100, 200, 250 and 400° C., respectively;

FIG. 10 is SEM pictures showing a surface of a TiN film formed by using TiCl₄ gas and MMH gas at a temperature of 400° C.; and

FIG. 11 is a timing view showing a film forming method in accordance with another embodiment of the present invention.

### DETAILED DESCRIPTION OF THE EMBODIMENTS

Embodiments of the present invention will now be described with reference to the accompanying drawings which form a part hereof.

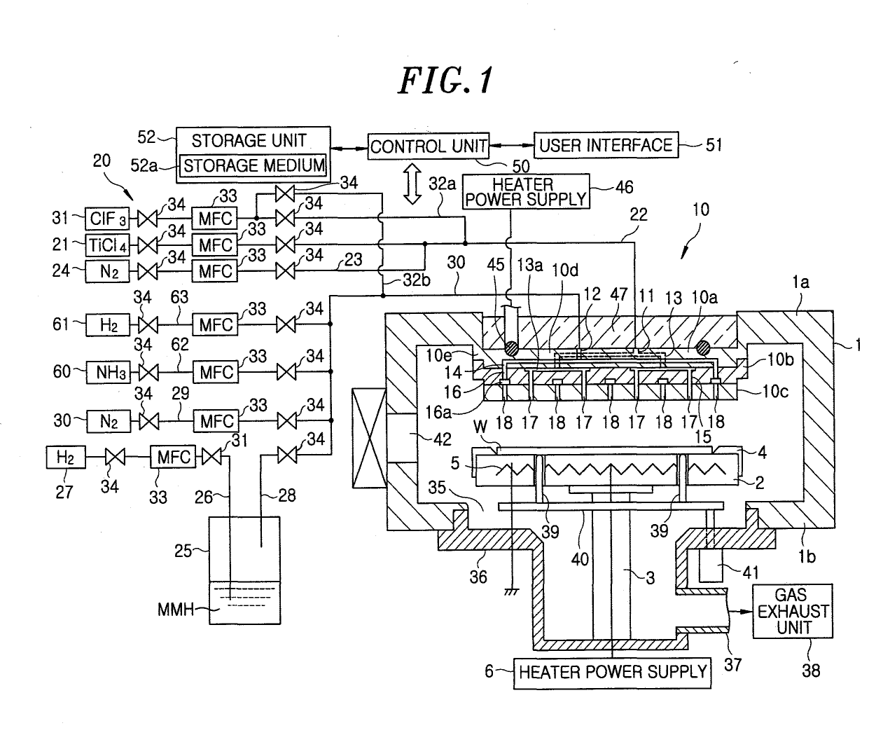

FIG. 1 is a schematic cross sectional view showing an example of a film forming apparatus 100 in use for performing a metal nitride film forming method in accordance with an embodiment of the present invention. In the present embodiment, a case of forming a TiN film by CVD is taken as an example.

In the following description, “mL/min” is employed as the unit of gas flow rate. Since the volume of a gas varies significantly depending on atmospheric pressure and temperature, the values are converted in terms of the standardized unit, i.e., “sccm (Standard Cubic Centimeter per Minutes),” which is used together with “mL/min” in the present embodiment. Here, the standardized unit corresponds to the temperature of 0° C. (273.15K) and the atmospheric pressure of 1 atm (101325 Pa).

The film forming apparatus 100 includes a chamber 1 having a substantially cylindrical shape. In the chamber 1, a susceptor 2 serving as a stage for horizontally supporting a target substrate, e.g., a wafer W, to be processed is disposed while being supported by a cylindrical supporting member 3 provided at a central lower portion thereof. The susceptor 2 is formed of, e.g., AlN. A guide ring 4 for guiding the wafer W is provided at an outer peripheral portion of the susceptor 2. Further, a heater 5 formed of a refractory metal, such as molybdenum or the like, is buried in the susceptor 2 and is powered from a heater power supply 6 to heat the wafer W to be maintained at a predetermined temperature. A shower head 10 having a substantially disk shape is provided at a ceiling wall 1a of the chamber 1. The shower head 10 includes an upper block body 10a, an intermediate block body 10b and a lower block body 10c. The upper block body 10a has a recessed shape and includes a horizontal portion 10d and an annular support 10e extended upwardly from a peripheral portion of the horizontal portion 10d. The horizontal portion 10d is included in a main body of the shower head 10 together with the intermediate block body 10b and the lower block body 10c. The shower head 10 is entirely supported by the annular support 10e.

Gas injection openings 17 and 18 are alternately formed in the lower block body 10c. A first and a second gas inlet port 11 and 12 are formed on an upper surface of the upper block body 10a. In the upper block body 10a, a plurality of gas passages 13 are branched from the first gas inlet port 11. Gas passages 15 are formed in the intermediate block body 10b, and the gas passages 13 communicate with the gas passages 15 through a horizontally extending communication path 13a. Further, the gas passages 15 communicate with the gas injection openings 17 of the lower block body 10c.

In the upper block body 10a, a plurality of gas passages 14 are branched from the second gas inlet port 12. Gas passages 16 are formed in the intermediate block body 10b, and the gas passages 14 communicate with the gas passages 16. Further, the gas passages 16 are connected to a horizontally extending communication path 16a in the intermediate block body 10b, and the communication path 16a communicates with the gas injection openings 18 of the lower block body 10c. Besides, the first and the second gas inlet port 11 and 12 are connected to gas lines of a gas supply unit 20.

The gas supply unit 20 includes a TiCl₄ gas supply source 21 for supplying TiCl₄ gas as Ti compound gas; a MMH tank 25 for storing monomethylhydrazine gas (hereinafter, referred to as “MMH gas”) serving as a first nitriding gas;

and a NH₃ gas supply source 60 for supplying NH₃ gas serving as a second nitriding gas.

A TiCl₄ gas supply line 22 is connected to the TiCl₄ gas supply source 21, and the TiCl₄ gas supply line 22 is connected to the gas inlet port 11. Further, a N₂ gas supply line 23 is connected to the TiCl₄ gas supply line 22, and N₂ gas is supplied from a N₂ gas supply source 24 to the N₂ gas supply line 23 as a carrier gas or a purge gas.

In the meantime, one end of a carrier gas supply line 26 is inserted into the MMH tank 25, and the other end thereof is connected to an N₂ gas supply source 27 for supplying N₂ gas serving as a carrier gas. Further, an MMH gas supply line 28 through which MMH gas serving as a nitriding gas is supplied is inserted into the MMH tank 25, and the MMH gas supply line 28 is connected to the second gas inlet port 12. Further, a purge gas supply line 29 is connected to the MMH gas supply line 28, and N₂ gas serving as a purge gas is supplied from an N₂ gas supply source 30 to the purge gas supply line 29. Connected to the MMH gas supply line 28 are an NH₃ and an H₂ gas supply line 62 and 63 for respectively supplying NH₃ gas serving as the second nitriding gas and H₂ gas, and an NH₃ and an H₂ gas supply source 60 and 61 are respectively connected to the NH₃ and the H₂ gas supply line 62 and 63.

The gas supply unit 20 further includes a ClF₃ gas supply source 31 for supplying ClF₃ gas serving as a cleaning gas, and a ClF₃ gas supply line 32a one end of which is connected to the ClF₃ gas supply source 31 is connected to the TiCl₄ gas supply line 22 at the other end thereof. Besides, a ClF₃ gas supply line 32b which is branched from the ClF₃ gas supply line 32a is connected to the MMH supply line 28.

A mass flow controller (MFC) 33 and two valves 34 are provided in each of the TiCl₄ gas supply line 22, the N₂ gas supply line 23, the carrier gas supply line 26, the purge gas supply line 29, the ClF₃ gas supply line 32a, the NH₃ gas supply line 62 and the H₂ gas supply line 63. Here, the MFC 33 is provided between the valves 34. The valves 34 are also provided in each of the MMH gas supply line 28 and the ClF₃ gas supply source 32b.

Accordingly, when the process is carried out, TiCl₄ gas and N₂ gas are respectively supplied from the TiCl₄ gas supply source 21 and the N₂ gas supply source 24 to the shower head 10 through the TiCl₄ gas supply line 22 and the first gas inlet port 11 of the shower head 10. Then, the TiCl₄ gas and the N₂ gas are injected from the gas injection openings 17 into the chamber 1 through the gas passages 13 and 15. In the meantime, MMH gas in the MMH tank 25 is supplied into the shower head 10 through the MMH gas supply line 28 and the second gas inlet port 12, together with a carrier gas from the N₂ gas supply source 27. Then, the MMH gas is injected from the gas injection openings 18 through the gas passages 14 and 16.

In other words, the shower head 10 is of a post-mix type, where the TiCl₄ gas and the MMH gas are completely independently supplied into the chamber 1, and the gases are mixed and react with each other after being injected thereto.

A heater (not shown) is provided in each of the MMH tank 25 and the MMH gas supply line 28 to vaporize MMH in the MMH tank 25 and to prevent the re-liquefaction of the MMH gas in the MMH gas supply line 28. When MMH is vaporized, MMH gas of saturated vapor pressure may be produced by heating the MMH tank 25 and used for the film formation without using a carrier gas instead of a bubbling method using N₂ carrier gas shown in FIG. 1.

Moreover, a heater 45 for heating the shower head 10 is provided in the horizontal portion 10d of the upper block body 10a of the shower head 10. The heater 45 is connected to and powered by a heater power supply 46 to heat the shower head 10 to a desired temperature. An insulating member 47 is provided in a recessed portion of the upper block body 10a so as to improve a heating efficiency of the heater 45.

A circular opening 35 is formed at a central portion of a bottom wall 1b of the chamber 1. In the bottom wall 1b, a gas exhaust room 36 is downwardly protrudently provided to cover the opening 35. A gas exhaust line 37 is connected to a side surface of the gas exhaust room 36, and a gas exhaust unit 38 is connected to the gas exhaust line 37. The inside of the chamber can be depressurized to a predetermined vacuum level by operating the gas exhaust unit 38.

Provided in the susceptor 2 are three wafer supporting pins 39 that are upwardly and downwardly movable with regard to the surface of the susceptor 2 to move the wafer W up and down while supporting it. In FIG. 1, only two of the wafer supporting pins 39 are shown. The wafer supporting pins 39 are supported by a supporting plate 40. The wafer supporting pins 39 are upwardly and downwardly moved together with the supporting plate 40 by a driving mechanism 41 such as an air cylinder or the like.

Provided in a sidewall of the chamber 1 are a loading/unloading port 42 for loading and unloading the wafer W between the chamber 1 and a wafer transfer chamber (not shown) provided adjacent to the chamber 1; and a gate valve 43 for opening and closing the loading/unloading port 42. As constituent members of the film forming apparatus 100, the heater power supplies 6 and 46, the valves 43, the mass flow controllers 33, the driving mechanism 41, and the like are connected to and controlled by a control unit 50 including a microprocessor (computer). Connected to the control unit 50 is a user interface 51 including a keyboard and/or a touch panel, through which a user performs a command input and the like to manage the film forming apparatus 100, and a display unit for visually displaying an operating status of the film forming apparatus 100.

Additionally connected to the control unit 50 is a storage unit 52 for storing a processing recipe, i.e., a program for performing the processing in each unit of the film forming apparatus 100. The processing recipe is stored in a storage medium 52a of the storage unit 52. The storage medium 52a may be a fixed unit such as hard disk or the like, or a portable unit such as CDROM, DVD or the like. Further, the recipe may be adequately transmitted from another device through, e.g., a dedicated line. As necessary, by calling a processing recipe from the storage unit 52 and executing it in the control unit 50 in accordance with an instruction or the like transferred from the user interface 51, a desired process is carried out in the film forming apparatus 100 under the control of the control unit 50.

Next, a TiN film forming method in the film forming apparatus 100 will be described.

First, the chamber 1 is depressurized to a vacuum level by the gas exhaust unit 38, and the chamber 1 is preliminarily heated to a temperature of 400° C. or lower, or preferably in the range between 50 and 400° C. by the heater 5, while N₂ gas is supplied from the N₂ gas supply source(s) 24 and/or 30 into the shower head 1. When the temperature of the chamber 1 stably reaches a desired level, TiCl₄ gas and N₂ gas which are respectively supplied from the TiCl₄ and the N₂ gas supply source 21 and 27 are alternately introduced at predetermined flow rates into the chamber 1 through the shower head 10, whereby a TiN film is pre-coated on the surfaces of members in the chamber 1, such as an inner wall of the chamber 1, an inner wall of the gas exhaust room 36, the shower head 10, and the like.

After such pre-coating process, the supply of the TiCl₄ gas and the N₂ gas is stopped. Then, a purge process is performed in the chamber 1 by supplying N₂ gas serving as a purge gas from the N₂ gas supply source(s) 24 and/or 30 into the chamber 1. Thereafter, as necessary, N₂ gas and MMH gas are supplied to perform a nitriding process on a surface of the formed thin TiN film.

Then, the gate valve 43 is opened, and a wafer W is loaded from the wafer transfer chamber (not shown) to the chamber 1 through the loading/unloading port 42 by a transfer unit (not shown). Then, the wafer W is mounted on the susceptor 2, and the gate valve 43 is closed. Thereafter, the inside of the chamber 1 is changed to a depressurized state (vacuum state). In the depressurized state, the wafer W is heated to a temperature of 400° C. or lower, or preferably in the range from 50 to 400° C. by the heater 5, whereby the preliminary heating of the wafer W is performed. Then, N₂ gas is supplied into the chamber 1. When the temperature of the wafer W is stabilized at a desired level, the film formation of a TiN film is started.

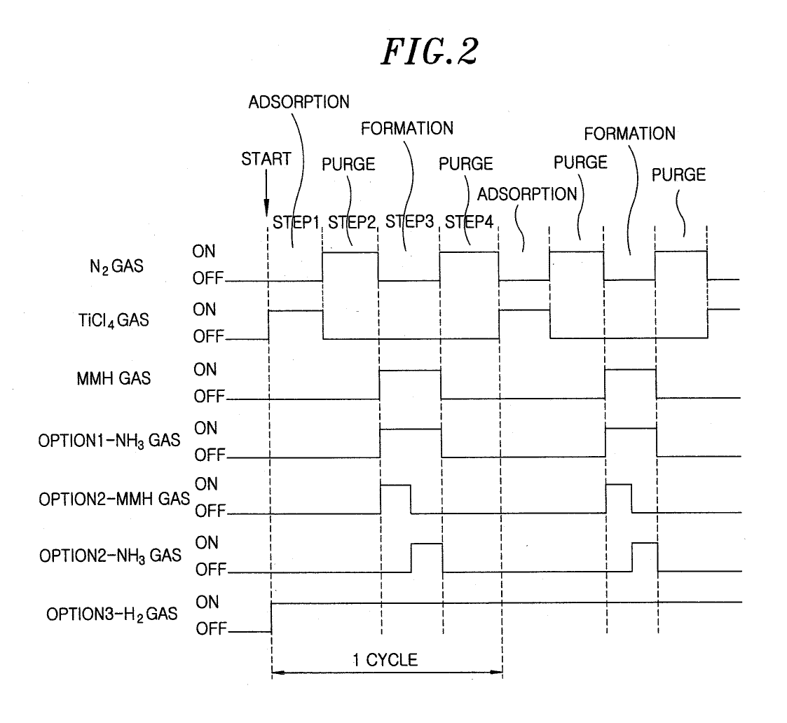

A first sequence example of the TiN film forming method of the present embodiment is a basic sequence using a timing view of N₂ gas, TiCl₄ gas, and MMH gas shown in FIG. 2. Specifically, step 1 is first executed for 0.1 to 10 seconds, wherein TiCl₄ gas supplied from the TiCl₄ gas supply source 21 is introduced into the chamber 1 together with N₂ gas serving as a carrier gas supplied from the N₂ gas supply source 24, whereby TiCl₄ is adsorbed on the wafer W. Successively, step 2 is executed for 0.1 to 10 seconds, wherein the supply of the TiCl₄ gas is stopped, N₂ gas serving as a purge gas is introduced from the N₂ gas supply source(s) 24 and/or 30 into the chamber 1, and a purge process is performed in the chamber 1.

Thereafter, step 3 is executed for 0.1 to 10 seconds, wherein the supply of the purge gas is stopped, MMH gas is introduced into the chamber 1 together with the N₂ gas supplied from the N₂ gas supply source 27, and a thermo-chemical reaction between the adsorbed TiCl₄ and MMH is made, whereby a TiN film is formed. Then, step 4 is executed for 0.1 to 10 seconds, wherein the supply of the MMH gas is stopped, N₂ gas serving as a purge gas is introduced from the N₂ gas supply source(s) 24 and/or 30 into the chamber 1, and a purge process is performed in the chamber 1.

A cycle of steps 1 to 4 is repeated a predetermined number of times, e.g., 10 to 500 times. At this time, the conversion of gases is carried out by controlling the valves based on commands transferred from the control unit 50.

The conditions for forming a TiN film preferably have the following ranges:

(1) Pressure inside chamber: 10 to 1000 Pa

(2) TiCl₄ gas flow rate: 1 to 200 mL/min (sccm)

(3) Carrier gas flow rate for TiCl₄ gas: 100 to 1000 mL/min (sccm)

(4) Carrier gas flow rate for MMH gas: 1 to 200 mL/min (sccm)

A second sequence example of the TiN film forming method of the present embodiment is a sequence using a timing view of N₂ gas, TiCl₄ gas, MMH gas and NH₃ gas (option 1) shown in FIG. 2. Specifically, NH₃ gas is simultaneously supplied in accordance with the supply timing of MMH gas in the first sequence example. Although the time period for which the MMH gas is supplied is unchanged, the supply of expensive MMH is reduced and inexpensive NH₃ makes up for the nitriding power instead of the expensive MMH.

A third sequence example of the TiN film forming method of the present embodiment is a sequence using a timing view of N₂ gas, TiCl₄ gas, MMH gas (option 2) and NH₃ gas (option 2) shown in FIG. 2. Specifically, the time period for which the MMH gas is supplied is divided into, e.g., two time periods, and MMH gas is supplied for a first time period and NH₃ gas is supplied for a second time period. A certain interval may be provided between the first and the second time period. In this way, it is also possible to reduce the supply of expensive MMH and make up for the nitriding power by using inexpensive NH₃ instead of the expensive MMH.

A fourth sequence example of the TiN film forming method of the present embodiment is a sequence using a timing view of H₂ gas (option 3) shown in FIG. 2. Specifically, H₂ gas serving as a reducing gas is supplied in the middle of forming the TiN film described above. Accordingly, although oxygen or the like enters the chamber 1 through a minute leak in the chamber 1 for example, the entered oxygen is reduced by supplying the H₂ gas in the middle of forming the TiN film, to thereby prevent the impurity, i.e., the oxygen from being included in the TiN film. After such TiN film formation, the inside of the chamber 1 is purged and the wafer W that has been subjected to the film formation is unloaded from the chamber 1. The TiN film formation is performed on a predetermined number of wafers W. Then, in the state in which no wafer is loaded, a cleaning process is carried out on gas exhaust lines, the shower head 10 and the chamber 1 by supplying ClF₃ gas serving as a cleaning gas thereto from the ClF₃ gas supply source 31.

As such, in the film formation of the present embodiment, by using MMH gas as the nitriding gas and alternately supplying TiCl₄ gas and MMH gas, it is possible to perform the TiN film formation in a lower temperature in the range of 400° C. or lower, or preferably from 50 to 400° C. as compared with the conventional film formation performed by using NH₃ gas as the nitriding gas. Further, in the case of using MMH gas, it is possible to form the TiN film in the lower temperature range from 50 to 400° C. at a higher film formation speed than that of the conventional film formation.

The reason will be described hereinafter.

MMH has the following structural formula F1 and is a material whose phase in a normal temperature is a liquid having a melting point of 87.5° C.

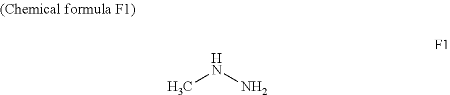

As shown in the structural formula F1, MMH has an N—N bond. Since, however, the N—N bond is easily broken, MMH has a higher reducibility than that of NH₃. Further, by performing the film formation with alternate use of TiCl₄ gas and MMH gas, it is possible to improve the reactivity of a reduction reaction. As a result, it is possible to lower the film formation temperature and increase the film formation speed. In addition, TiN is produced through the reaction of TiCl₄ and MMH based on the following reaction formula F2 and, at this time, CH_{2Cl}₂ is also produced. This makes it easier to remove Cl, to thereby reduce a remaining amount of Cl of the film as compared with the conventional method of employing NH₃ as the nitriding gas. Accordingly, it is possible to form a TiN film at a lower temperature and reduce a resistivity of the TiN film by employing MMH gas as the nitriding gas.

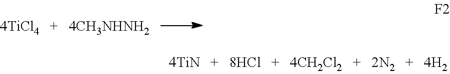

As for the TiN film formation using TiCl₄ gas and MMH gas, the properties of the TiN film to be formed may be divided into three stages depending on temperature groups as follows.

(1) First group in a temperature range between 330 and 400° C. including 400° C. (high temperature group)

(2) Second group in a temperature range from 230 to 330° C. (intermediate temperature group)

(3) Third group in a temperature range between 50 and 230° C. including 50° C. (low temperature group)

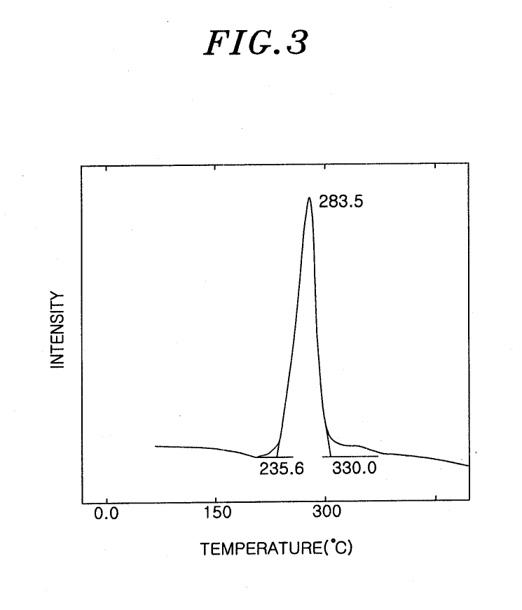

When a liquid MMH was heated, a relationship between the temperature and the heat discharge rate was obtained by using a DSC (Differential Scanning calorimeter). As shown in FIG. 3, it has been resultantly seen that an exothermic peaking started from about 230° C.; the peak was reached at 284° C.; and the exothermic peaking disappeared at about 330° C. This indicates that an autolysis of MMH starts from about 230° C., and the autolysis of MMH ends in about 330° C. It is considered that a crystallized TiN film is easily formed due to higher activity at the temperature of 230° C. or higher at which the autolysis starts.

Accordingly, the TiN film having mainly a crystalline state is formed in the high temperature group (1) and the intermediate group (2), while the TiN film having mainly an amorphous state is formed in the low temperature group (3). The crystallized TiN film has a lower resistivity than that of the amorphous TiN film. In the meantime, since no grain boundary exists in the amorphous TiN film, the amorphous TiN film has a satisfactory film continuity, a good surface morphology, and a higher barrier property. Besides, in the intermediate temperature group (2), the TiN film has fine crystal grains of TiN crystal; a higher flatness of surface and a satisfactory continuity of a film; and a higher barrier property than that of the TiN film formed in the high temperature group (3).

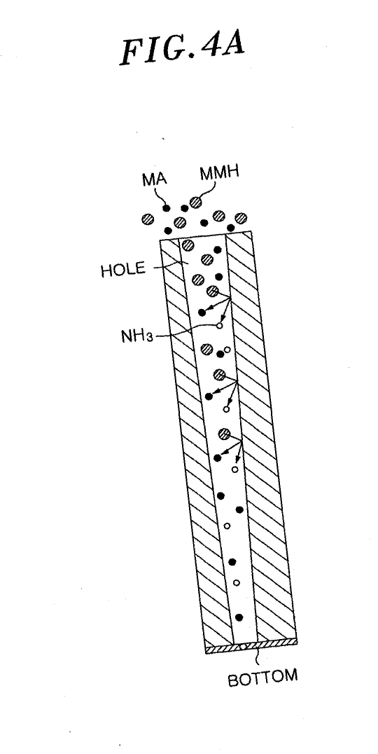

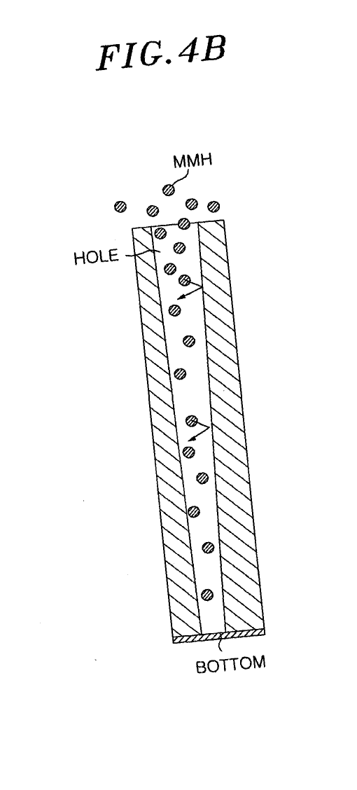

When the TiN film is formed on the bottom of a contact hole by using TiCl₄ gas and MMH gas, if the wafer temperature exceeds 330° C. at which the autolysis is ended, as shown in FIG. 4A, MMH is decomposed into methylamine (CH₃NH₂) (MA) and ammonia (NH₃) at an intermediate height portion of the contact hole by a thermal reaction with a sidewall, and MMH is depleted at a bottom portion. This causes the step coverage to be deteriorated.

On the other hand, if the wafer temperature is lower than 230° C. at which the autolysis starts, as shown in FIG. 4B, MMH reaches the bottom portion of the contact hole without being decomposed. Accordingly, a satisfactory film formation reaction occurs at the bottom portion, thereby obtaining satisfactory step coverage (buriability). If the wafer temperature ranges from 230 to 330° C., MMH is not completely depleted and a certain amount of MMH reaches the bottom portion, thereby obtaining sufficient step coverage (buriability). In brief, the step coverage (buriability) is not sufficient in the high temperature group (1), while satisfactory step coverage is achieved in the intermediate and the low temperature group (2) and (3).

FIG. 5 shows a temperature dependency of a backside deposition amount, serving as the index of step coverage, when a TiN film is actually formed by using TiCl₄ gas and MMH gas. Specifically, FIG. 5 shows a result of measuring how much amount of deposition is made on a backside surface of a wafer in the range of several millimeters from an edge of the wafer when the TiN film is formed on the surface of the wafer. More deposition amount causes the buriability of gap to be more satisfactory.

As shown in FIG. 5, if the wafer temperature becomes lower than about 330° C., the backside deposition amount is sharply increased. In other words, it is seen that more satisfactory buriability is obtained by decreasing the wafer temperature to be lower than the range of the intermediate temperature group (2). In the meantime, inflection points exist at about 230 and about 330° C. in FIG. 5. This may be caused by the fact that the decomposition of MMH starts at 230° C. and ends at 330° C.

Further, the film formation speed is increased by using MMH gas as a nitriding gas. If the high temperature group (1) and the intermediate temperature group (2) are compared, higher film formation speed is achieved from the high temperature group (1) having a range that is higher than that of the intermediate temperature group (2). In the low temperature group (3), an amorphous TiN film is formed at a low temperature that is lower than 230° C. at a high film formation speed.

The film stress becomes getting smaller in the order of the high temperature group (1), the intermediate temperature group (2) and the low temperature group (3).

From described above, the high temperature group (1) is adequate for cases requiring a low resistivity but not requiring the step coverage (buriability), for example, for a solid film such as a cap, a hard mask or the like; or an upper barrier film having a small aspect ratio (about 1 to 5). The intermediate temperature group (2) is adequate for cases requiring a low resistivity and a satisfactory step coverage (buriability), for example, for a capacitor electrode of a DRAM. The low temperature group (3) is adequate for cases requiring a satisfactory step coverage and a high barrier property, for example, for a barrier film of wiring or plug.

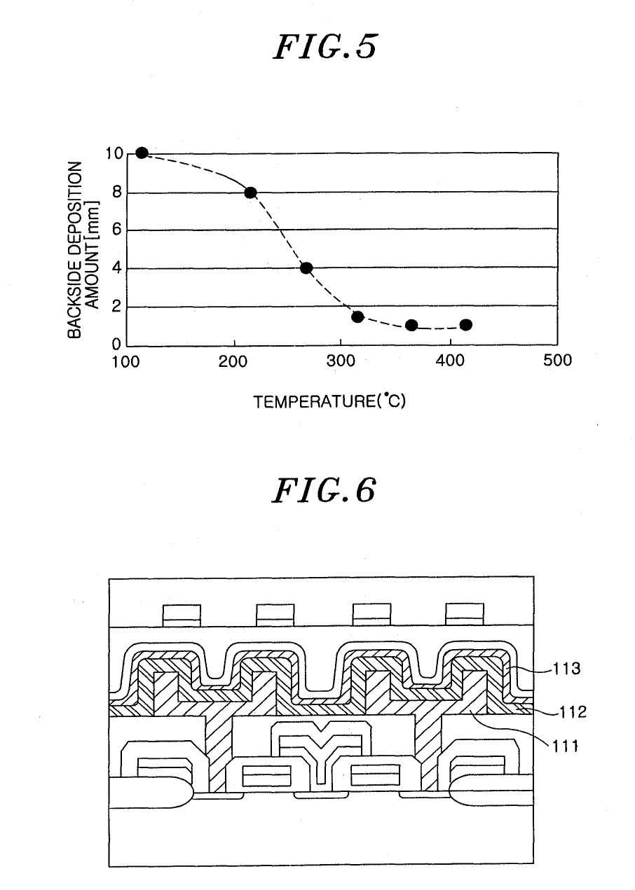

Films formed in the high, the intermediate and the low temperature group may be adequately combined and used. For example, as an upper electrode of a DRAM, TiN films formed in the intermediate and the low temperature group may be combined and used. FIG. 6 shows a configuration of a DRAM capacitor. In FIG. 6, the reference numeral “111” indicates a lower electrode, and a dielectric film 112 is formed of a high-k material on the lower electrode 111; and an upper electrode 113 is formed on the dielectric film 112.

In the case of forming a TiN film as the upper electrode, if the TiN film is conventionally formed by using a reducing agent such as NH₃, the film formation temperature reaches about 450° C. at the lowest, and the stress of the formed TiN film ranges from 0.8 to 0.9 GPa. Accordingly, if the TiN film that has been formed to have the film formation temperature of about 450° C. at the least and the stress in the range from 0.8 to 0.9 GPa is formed on the dielectric film 112, this causes crystallization of the dielectric film 112 and, thus, a leak current is increased due to the grain boundary.

On the other hand, if the TiN film as the upper electrode 113 is formed by applying the film formation using the lower and the intermediate temperature group, this makes it possible to prevent the crystallization of the dielectric film 112. Specifically, a thin amorphous TiN film serving as a cushion member having a small stress is first formed on the dielectric film 112 in the lower temperature group, and a TiN film is formed in the intermediate temperature group on the thin amorphous TiN film to serve as the upper electrode 113. In this case, the temperature that is required for the dielectric film 112 reaches, at the highest, about 330° C. in the intermediate temperature group, and the film stress in the intermediate temperature group reaches a value, e.g., about 0.4 GPa, which is about half of that of the conventional TiN film.

As a result, the crystallization of the dielectric film 112 is prevented and, thus, it is possible to manufacture a DRAM capacitor having a small leak current. Moreover, in the case of combining the films formed in the high, the intermediate and the low temperature group, the film formation may be carried out in the same chamber or separate chambers.

Preferably, the high temperature group (1) ranges from 350 to 400. The low temperature group (3) preferably ranges from 100 to 200° C.

Next, the result of actually forming a TiN film in accordance with the film forming method of the present embodiment will be described.

In the present embodiment, the TiN film was formed while variously changing the wafer temperature. Other conditions except for the temperature are as follows.

Chamber pressure: 90 Pa

TiCl₄ gas flow rate: 28 mL/min (sccm)

(Flow rate per unit area of wafer: 0.04 sccm/cm²)

TiCl₄ gas supply time (per cycle): 1 sec.

N₂ purge flow rate: 3500 mL/min (sccm)

(Flow rate per unit area of wafer: 5 sccm/cm²)

N₂ purge time (per cycle): 2 sec.

MMH gas flow rate: 28 mL/min (sccm)

(Flow rate per unit area of wafer: 0.04 sccm/cm²)

MMH gas supply time (per cycle): 1 sec.

N₂ purge flow rate: 3500 mL/min (sccm)

(Flow rate per unit area of wafer: 5 sccm/cm²)

N₂ purge time (per cycle): 6 sec.

For the comparison, the TiN film was conventionally formed by using NH₃ instead of MMH gas while variously changing the wafer temperature. Other conditions except for the temperature are as follows.

Chamber pressure: 90 Pa

TiCl₄ gas flow rate: 28 mL/min (sccm)

(Flow rate per unit area of wafer: 0.04 sccm/cm²)

TiCl₄ gas supply time (per cycle): 1 sec.

N₂ purge flow rate: 3500 mL/min (sccm)

(Flow rate per unit area of wafer: 5 sccm/cm²)

N₂ purge time (per cycle): 2 sec. NH₃ gas flow rate: 28 mL/min (sccm) (Flow rate per unit area of wafer: 4 sccm/cm²)

NH₃ gas supply time (per cycle): 1 sec.

N₂ purge flow rate: 3500 mL/min (sccm)

(Flow rate per unit area of wafer: 5 sccm/cm²)

N₂ purge time (per cycle): 6 sec.

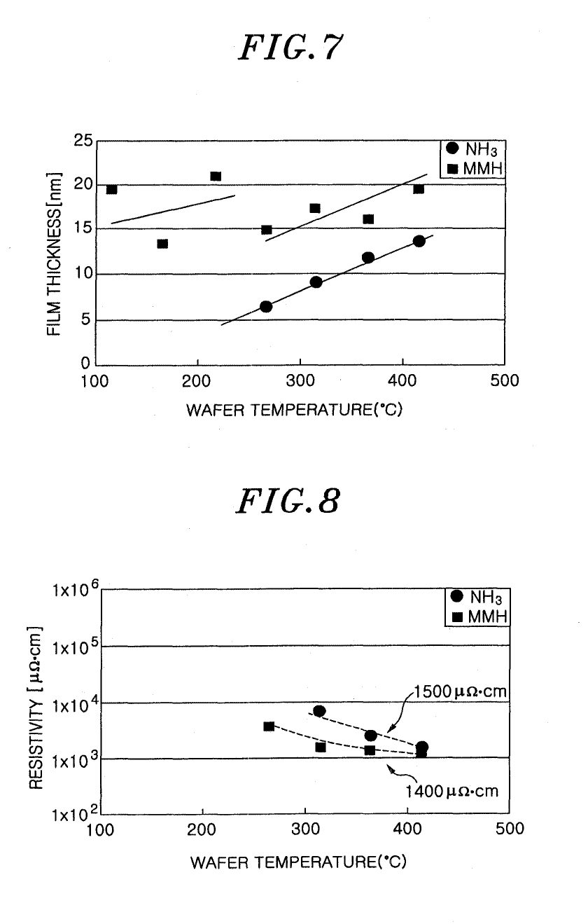

As for the obtained films, a relationship between the wafer temperature and the film thickness during the film formation is acquired and shown in FIG. 7. As shown in FIG. 7, it is seen that the film formation using MMH gas as a nitriding gas results in a thicker film thickness and a higher film formation speed than those of the film formation using NH₃ gas. Moreover, it is seen that a thick film thickness is obtained even at a low temperature of 100° C. by using MMH gas as the nitriding gas.

Further, as for the obtained films, a relationship between the wafer temperature and the resistivity during the film formation is acquired and shown in FIG. 8. As shown in FIG. 8, it is seen that the film formation using MMH gas as the nitriding gas results in a smaller resistivity than that of the film formation using NH₃ gas.

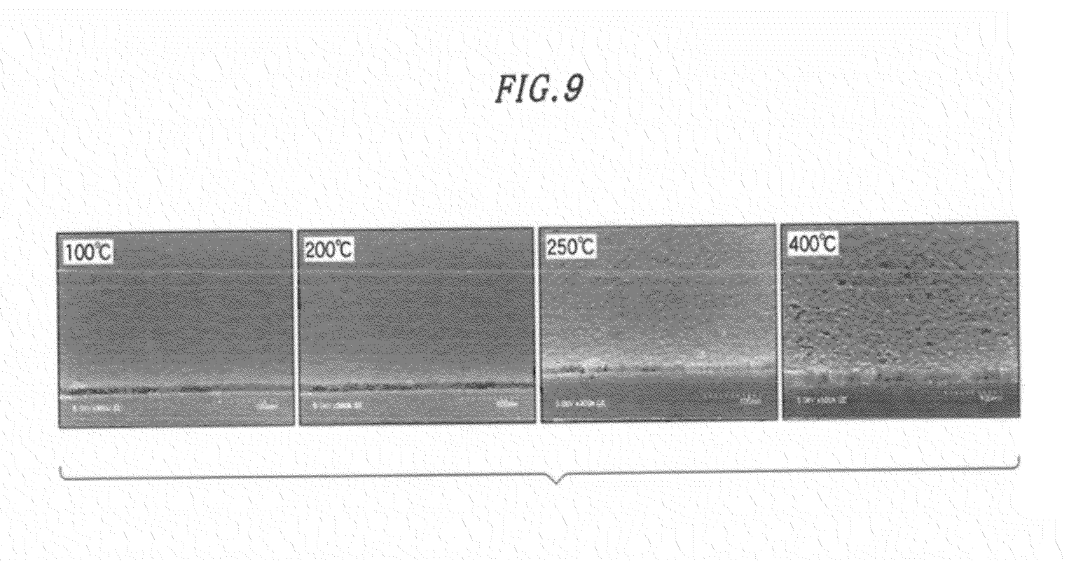

In addition, surfaces states of TiN films formed by using TiCl₄ gas and MMH gas at the temperatures of 100, 200, 250 and 400° C., respectively, were acquired. FIG. 9 is SEM (Scanning Electron Microscope) pictures showing the surfaces of the TiN films. As shown in FIG. 9, TiN grain boundaries are observed on the surfaces of TiN films formed at the temperatures of 400 and 250° C. Here, the TiN film formed at the temperature of 250° C. has a finer crystal grain and a higher flatness than the TiN film formed at the temperature of 400° C. As the results of measuring crystalline orientations of the TiN films formed at the temperatures of 400 and 250° C. by using an XRD (X-Ray diffractometer), it is seen that peaks are obtained in TiN crystals.

On the other hand, it is seen that the surfaces of the TiN films formed at the temperatures of 100 and 200° C. have no grain boundary and significantly high flatness. As the results of measuring crystalline orientations of the TiN films formed at the temperatures of 100 and 200° C. by using the XRD, it is seen that a peak indicating the crystal is not obvious and the TiN films are under an amorphous state.

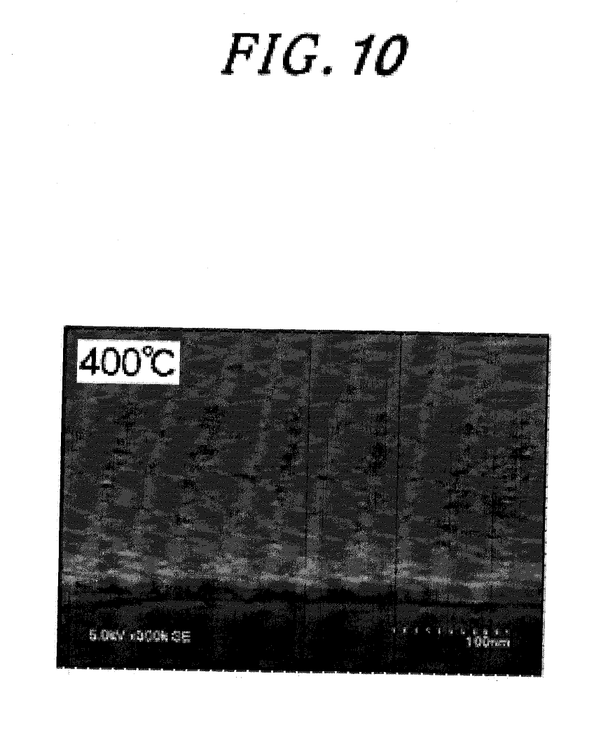

For the comparison, FIG. 10 is a SEM picture showing a surface of a TiN film formed by using NH₃ as the nitriding gas at the temperature of 400° C. As shown in FIG. 10, the surface of the TiN film formed by using NH₃ as the nitriding gas at the temperature of 400° C. is of a crystalloid state that is similar to that of the TiN film formed by using MMH gas at the temperature of 250° C.

As such, in accordance with the present embodiment, it is possible to form a metal nitride film, e.g., a TiN film, on a wafer serving as a target substrate to be processed by alternately supplying a metal chloride, e.g., TiCl₄ gas, and a hydrazine compound gas, e.g., MMH gas, while heating the target substrate, to thereby perform the film formation at a lower temperature at a higher film formation speed.

In addition, it is possible to form a TiN film having mainly a TiN crystalloid state on the wafer serving as a target substrate to be processed by alternately supplying TiCl₄ gas and MMH gas to the chamber serving as a processing vessel while heating the wafer at a temperature within the high temperature group ranging between 330 and 400° C. including 400° C., to thereby obtain the TiN film to have a high film formation speed and a low resistivity.

Besides, it is possible to form a TiN film having mainly a TiN crystalloid state on the wafer serving as a target substrate to be processed by alternately supplying TiCl₄ gas and MMH gas to the chamber serving as a processing vessel while heating the wafer at a temperature within the intermediate temperature group ranging from 230 to 330° C., to thereby obtain the TiN film to have a low resistivity and a satisfactory step coverage (buriability).

Furthermore, it is possible to form a TiN film having mainly a TiN crystalloid state on the wafer serving as a target substrate to be processed by alternately supplying TiCl₄ gas and MMH gas to the chamber serving as a processing vessel while heating the wafer at a temperature within the low temperature group ranging between 50 and 230° C. including 50° C., to thereby obtain the TiN film to have a satisfactory step coverage (buriability) and a high barrier property.

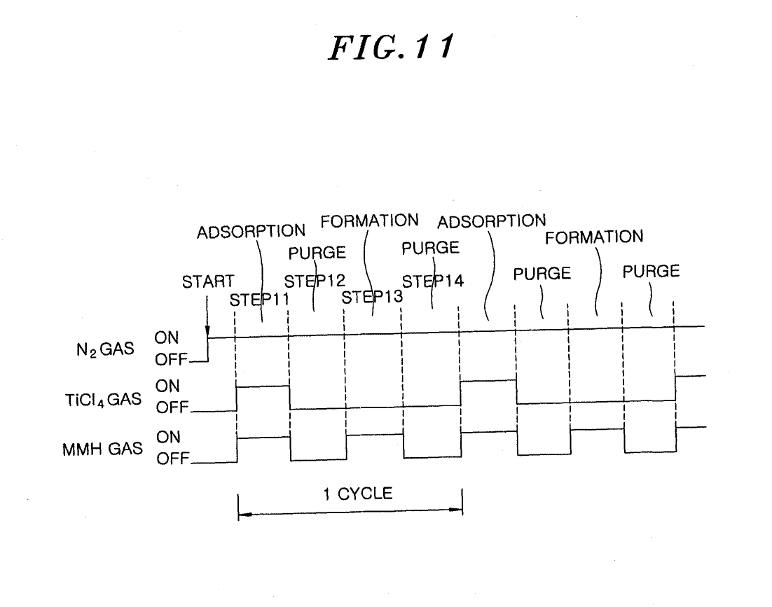

The present invention is not limited to the above embodiments, and various modifications are possible. For example, in the above embodiments, when TiCl₄ gas and MMH gas are alternately supplied, one cycle for supplying TiCl₄ gas, a purge gas, MMH gas and a purge gas is performed one or more times. The present invention, however, is not limited to the above embodiments. For example, as shown in FIG. 11, one cycle including a simultaneous supply of TiCl₄ gas and MMH gas (TiN film formation: step 11); a purge process (step 12); a supply of MMH gas (nitriding: step 13); and a purge process (step 14) may be performed one or more times.

In addition, although the case of employing MMH gas as the nitriding gas is taken as an example in the above embodiments, a hydrazine compound, shown in the following chemical formula F3, including an N—N bond having a high reducing power may be employed as the nitriding gas. For example, hydrazine, dimethyl hydrazine, tertiary butyl hydrazine, or the like may be employed.

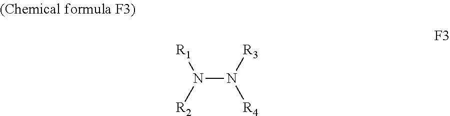

Here, R₁, R₂, R₃ and R₄ indicate hydrogen or monovalent hydrocarbons.

Furthermore, although the case of employing a TiN film as the metal nitride film is taken as an example in the above embodiment, a process for obtaining a nitride by reducing/nitriding a metal chloride into a hydrazine compound, e.g., MMH, may be applied. For example, a TaN film, a NiN film or a WN film may be employed.

Besides, the target substrate to be processed may be another type substrate, e.g., a substrate for a liquid crystal display such as FPD, without being limited to a semiconductor wafer.

What is claimed is:

1. A metal nitride film forming method for forming a metal nitride film, the method comprising:
loading a target substrate to be processed into a processing chamber and maintaining an inside of the processing chamber under a depressurized state;
maintaining the target substrate in the processing chamber at a temperature of 400° C. or lower; and
forming a metal nitride film on the target substrate by alternately supplying a metal chloride gas and a hydrazine compound gas into the processing chamber,
wherein NH₃ gas is supplied in conjunction with the supply of the hydrazine compound gas.

2. The method of claim 1, wherein the NH₃ gas is supplied simultaneously with the hydrazine compound gas.

3. The method of claim 1, wherein the NH₃ gas is supplied at a different timing from the supply of the hydrazine compound gas.

4. The method of claim 1, wherein the metal chloride gas includes TiCl₄ gas, the hydrazine compound gas includes monomethyl hydrazine gas and the metal nitride film includes a TiN film.

5. The method of claim 4, wherein the formed TiN film is mainly of a TiN crystalloid state.

6. The method of claim 4, wherein the formed TiN film is mainly of an amorphous state.

7. The method of claim 1, wherein one cycle including supplying the metal chloride gas into the processing chamber; purging the processing chamber; supplying the hydrazine compound gas into the processing chamber; and purging the processing chamber is carried out one or more times.

8. The method of claim 1, wherein, in the maintaining of the target substrate, the target substrate is maintained at a temperature ranging between 330 and 400° C. including 400° C.

9. The method of claim 1, wherein, in the maintaining of the target substrate, the target substrate is maintained at a temperature ranging from 230 to 330° C.

10. The method of claim 1, wherein, in the maintaining of the target substrate, the target substrate is maintained at a temperature ranging between 50 and 230° C. including 50° C.

11. A metal nitride film forming method for forming a metal nitride film, the method comprising:
maintaining a target substrate to be processed at a temperature ranging between 50 and 230° C. including 50° C. and forming a TiN film mainly of an amorphous state on the target substrate by alternately supplying TiCl₄ gas and monomethyl hydrazine gas into the target substrate; and
maintaining the target substrate at a temperature ranging from 230 to 330° C. and forming a TiN film mainly of a TiN crystalloid state on the TiN film mainly of the amorphous state by alternately supplying TiCl₄ gas and monomethyl hydrazine gas into the target substrate.
